(19) United States
(12) Patent Application Publication
(10) Pub. No.: US 2026/0040441 A1
(43) Pub. Date: Feb. 5, 2026

(54) WIRING SUBSTRATE AND METHOD FOR MANUFACTURING WIRING SUBSTRATE

(71) Applicant: IBIDEN CO., LTD., Gifu (JP)

(72) Inventor: Kosei OSADA, Gifu (JP)

(73) Assignee: IBIDEN CO., LTD., Gifu (JP)

(21) Appl. No.: 19/285,280

(22) Filed: Jul. 30, 2025

(30) Foreign Application Priority Data
Aug. 1, 2024 (JP) 2024-126039

(51) Int. Cl. H05K 1/02; H05K 3/18

(52) U.S. Cl. CPC H05K 1/0298; H05K 3/181

(57) ABSTRACT

A wiring substrate includes a first insulating layer, a conductor layer formed on the first insulating layer, and a second insulating layer formed on the first insulating layer such that the second insulating layer is covering the conductor layer. The conductor layer includes wirings formed such that the wirings have the minimum wiring width of 3 μm or less and the minimum inter-wiring distance of 3 μm or less and that the conductor layer has mesh-like unevenness formed on a side surface of the conductor layer and not on an upper surface of the conductor layer.

### CROSS-REFERENCE TO RELATED APPLICATIONS

The present application is based upon and claims the benefit of priority to Japanese Patent Application No. 2024-126039, filed Aug. 1, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2000-252622 describes a printed wiring substrate. The entire contents of this publication are incorporated herein by reference.

### SUMMARY OF THE INVENTION

According to one aspect of the present invention, a wiring substrate includes a first insulating layer, a conductor layer formed on the first insulating layer, and a second insulating layer formed on the first insulating layer such that the second insulating layer is covering the conductor layer. The conductor layer includes wirings formed such that the wirings have the minimum wiring width of 3 μm or less and the minimum inter-wiring distance of 3 μm or less and that the conductor layer has mesh-like unevenness formed on a side surface of the conductor layer and not on an upper surface of the conductor layer.

According to another aspect of the present invention, a method for manufacturing a wiring substrate includes forming a metal film layer on a first insulating layer, forming a resist layer having openings on the metal film layer, and forming a plating film layer on the metal film layer in the openings formed in the resist layer. The forming of the resist layer includes exposing the resist layer by direct imaging exposure such that the openings have mesh-like unevenness formed on side walls of the resist layer in the openings, and the forming of the plating film layer includes forming an uneven shape on a side surface of the plating film layer such that the side surface of the plating film layer replicates the mesh-like unevenness.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a region (II) in FIG. 1;

FIG. 3 is a perspective view for describing a conductor layer included in a wiring substrate according to an embodiment of the present invention;

FIG. 4 is a side view for describing a conductor layer included in a wiring substrate according to an embodiment of the present invention;

FIG. 5A is a cross-sectional view illustrating an example of a method for manufacturing the wiring substrate illustrated in FIG. 1;

FIG. 5B is a cross-sectional view illustrating an example of the method for manufacturing the wiring substrate illustrated in FIG. 1;

FIG. 5C is a cross-sectional view illustrating an example of the method for manufacturing the wiring substrate illustrated in FIG. 1;

FIG. 5D is a cross-sectional view illustrating an example of the method for manufacturing the wiring substrate illustrated in FIG. 1;

FIG. 5E is a cross-sectional view illustrating an example of the method for manufacturing the wiring substrate illustrated in FIG. 1;

FIG. 5F is a cross-sectional view illustrating an example of the method for manufacturing the wiring substrate illustrated in FIG. 1;

FIG. 5G is a perspective view illustrating a resist layer in the method for manufacturing the wiring substrate illustrated in FIG. 1;

FIG. 5H is a side view illustrating the resist layer in the method for manufacturing the wiring substrate illustrated in FIG. 1;

FIG. 5I illustrates an example of the method for manufacturing the wiring substrate illustrated in FIG. 1;

FIG. 5J illustrates an example of the method for manufacturing the wiring substrate illustrated in FIG. 1;

FIG. 5K illustrates an example of the method for manufacturing the wiring substrate illustrated in FIG. 1;

FIG. 5L illustrates an example of the method for manufacturing the wiring substrate illustrated in FIG. 1;

FIG. 5M illustrates an example of the method for manufacturing the wiring substrate illustrated in FIG. 1;

FIG. 5N illustrates an example of the method for manufacturing the wiring substrate illustrated in FIG. 1; and

FIG. 5O illustrates an example of the method for manufacturing the wiring substrate illustrated in FIG. 1.

### DETAILED DESCRIPTION OF THE EMBODIMENTS

Embodiments will now be described with reference to the accompanying drawings, wherein like reference numerals designate corresponding or identical elements throughout the various drawings.

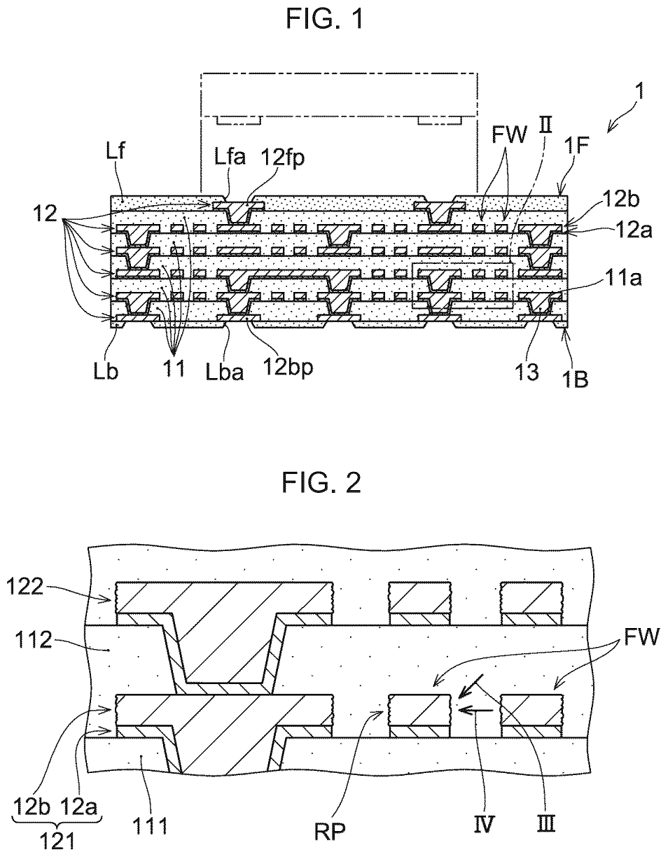

FIG. 1 is a cross-sectional view illustrating a wiring substrate 1 according to an embodiment of the present invention. A laminated structure, and the number of conductor layers and the number of insulating layers, of the wiring substrate of the embodiment are not limited to the laminated structure of the wiring substrate 1 of FIG. 1, and the number of conductor layers and the number of insulating layers included in the wiring substrate 1.

The wiring substrate 1 has two surfaces (a first surface (1F) and a second surface (1B) on the opposite side with respect to the first surface (1F)) orthogonal to a thickness direction thereof. The wiring substrate 1 includes insulating layers 11 and conductor layers 12 that are alternately laminated. Conductor layers 12 facing each other across a single insulating layer 11 are connected by via conductors 13. In the illustrated example, the conductor layer 12 forming a part of the first surface (1F) is patterned to include multiple conductor pads (12fp). The conductor layer 12 forming a part of the second surface (1B) is patterned to include multiple conductor pads (12bp).

In the description of the wiring substrate 1 illustrated in FIG. 1, the first surface (1F) side of the wiring substrate 1 is also referred to as “upper” or an “upper side”, and the second surface (1B) side of the wiring substrate 1 is also referred to as “lower” or a “lower side”. Further, for each of the structural elements, a surface facing the first surface (1F) side of the wiring substrate 1 is also referred to as an “upper surface”, and a surface facing the second surface (1B) side of the wiring substrate 1 is also referred to as a “lower surface”.

The insulating layers 11 can be formed, for example, using an insulating resin such as an epoxy resin, or a phenol resin. The insulating layers 11 may contain one of a fluorine resin, a liquid crystal polymer (LCP), a fluoroethylene resin (PTFE), a polyester resin (PE), and a modified polyimide resin (MPI).

Examples of a conductor constituting the conductor layers 12 and the via conductors 13 include copper, nickel, and the like, and copper is preferably used. The conductor layers 12 and the via conductors 13 each have a multilayer structure. The conductor layers 12 and the via conductors 13 each have a two-layer structure including a metal film layer (12a), which is preferably a copper sputtering film layer or an electroless copper plating film layer, and a plating film layer (12b), which is preferably an electrolytic copper plating film layer.

Each via conductor 13 penetrating an insulating layer 11 in the thickness direction is formed by filling a through hole (11a) penetrating the insulating layer 11 with a conductor. In the example of FIG. 1, each via conductor 13 is integrally formed with a conductor layer 12 provided on an upper side thereof. Therefore, the via conductor 13 and the conductor layer 12 can be formed by the same metal film layer and plating film layer.

In the example of FIG. 1, the wiring substrate 1 includes a solder resist layer (Lf) formed on the uppermost insulating layer 11 and conductor layer 12, as well as a solder resist layer (Lb) formed under the lowermost insulating layer 11 and conductor layer 12. The solder resist layers (Lf, Lb) are formed, for example, using a photosensitive polyimide resin or epoxy resin. Openings (Lfa) are formed in the solder resist layer (Lf), and the conductor pads (12fp) are exposed from the openings (Lfa). Openings (Lba) are formed in the solder resist layer (Lb), and the conductor pads (12bp) are exposed from the openings (Lba). That is, the first surface (1F) of the wiring substrate 1 includes a surface of the solder resist layer (Lf) and surfaces of the conductor pads (12fp), and the second surface (1B) of the wiring substrate 1 includes a surface of the solder resist layer (Lb) and surfaces of the conductor pads (12bp).

The first surface (1F) of the wiring substrate 1 constitutes a component mounting surface to which external electronic components can be connected. The second surface (1B) on the opposite side with respect to the component mounting surface of the wiring substrate 1 can be a connection surface that is to be connected to an external element such as an external wiring substrate (for example, a motherboard of any electrical device) when the wiring substrate 1 itself is mounted on the external element.

The conductor layers 12 included in the wiring substrate 1 are patterned to have predetermined conductor patterns. The conductor layers 12 include relatively fine wirings and shave relatively high-density circuit wirings. Specifically, the conductor layers 12 of the wiring substrate 1 have wirings (FW), which are high-density wirings with relatively small wiring widths and inter-wiring distances (wiring intervals). The wirings (FW) have a minimum wiring width of 3 μm or less, and a minimum inter-wiring distance of 3 μm or less. In the illustrated example, among the multiple conductor layers 12 included in the wiring substrate 1, four conductor layers 12 are provided with the wirings (FW), which are high-density wirings. In the wiring substrate 1, any number of conductor layers 12 may be provided with the wirings (FW). The number of conductor layers 12 in the wiring substrate 1 that include the wirings (FW) is not limited.

When the conductor layers 12 are formed to include the wirings (FW) as described above, it may be preferable that the via conductors 13 connecting conductor layers 12 facing each other across an insulating layer 11 are also formed at a fine pitch. The through holes (11a) for the via conductors 13 with small diameters can be formed in the insulating layers 11. Therefore, although the insulating layers 11 can contain inorganic fillers such as fine particles of silica (SiO₂), alumina, mullite, or the like, in order to facilitate the formation of the through holes (11a) with small diameters, it may be preferable that the insulating layers 11 do not contain inorganic fillers. Further, it is also preferable that insulating layers 11 do not contain a core material (reinforcing material) formed of glass fiber, aramid fiber, or the like. In the wiring substrate 1, for example, the insulating layers 11 each have a thickness of 3 μm to 15 μm, and the conductor layers 12 each have a thickness of 5 μm or less.

Next, with reference to FIGS. 2 to 4, a structure of the conductor layers 12 included in the wiring substrate 1 is described in detail. In the description with reference to FIG. 2 to 4, for the sake of simplicity in description, the lowermost insulating layer among the insulating layers illustrated in FIG. 2 is referred to as a first insulating layer 111, and the conductor layer formed in contact with an upper surface of the first insulating layer 111 is referred to as a first conductor layer 121. Further, the insulating layer formed on the first conductor layer 121 and on the first insulating layer 111 exposed from the conductor patterns of the first conductor layer 121 is referred to as a second insulating layer 112, and the conductor layer formed in contact with an upper surface of the second insulating layer 112 is referred to as a second conductor layer 122.

FIG. 2 illustrates an enlarged view of a region (II) surrounded by a one-dot chain line in FIG. 1. As illustrated, unevenness (Wrp) is formed on side surfaces of the conductor patterns of the first conductor layer 121, which includes the wirings (FW). As will be described later in detail in the method for manufacturing the wiring substrate, the unevenness (Wrp) is a replicated shape formed on a side surface of the plating film layer (12b), the shape being transferred from an uneven shape formed on sidewalls of openings in a plating resist layer during the formation of the plating film layer (12b). Therefore, the unevenness (Wrp) is formed in a portion of the first conductor layer 121 that is composed of the plating film layer (12b), and is not formed in a portion composed of the metal film layer (12a). Further, the unevenness (Wrp) is not formed on an upper surface of the first conductor layer 121. Here, the term “replicated” means that a shape with inverted unevenness is formed on an object (in this case, the plating film layer (12b)).

Since the unevenness (Wrp) is formed on the side surface of the first conductor layer 121, it is thought that the second insulating layer 112 that covers the first conductor layer 121 is firmly adhered to the side surface of the first conductor layer 121. The upper surface of the first conductor layer 121, on which the unevenness (Wrp) is not formed, has good flatness. Therefore, it is thought that the relatively fine wirings (FW) can be formed with a thickness that faithfully follows a design value. Further, the upper surface of the second insulating layer 112, which is positioned directly above the upper surface of the first conductor layer 121, can also be formed as a surface with good flatness. Therefore, it is thought that the conductor patterns of the second conductor layer 122, which is formed in contact with the upper surface of the second insulating layer 112, also can be formed with dimensions that faithfully follow design values.

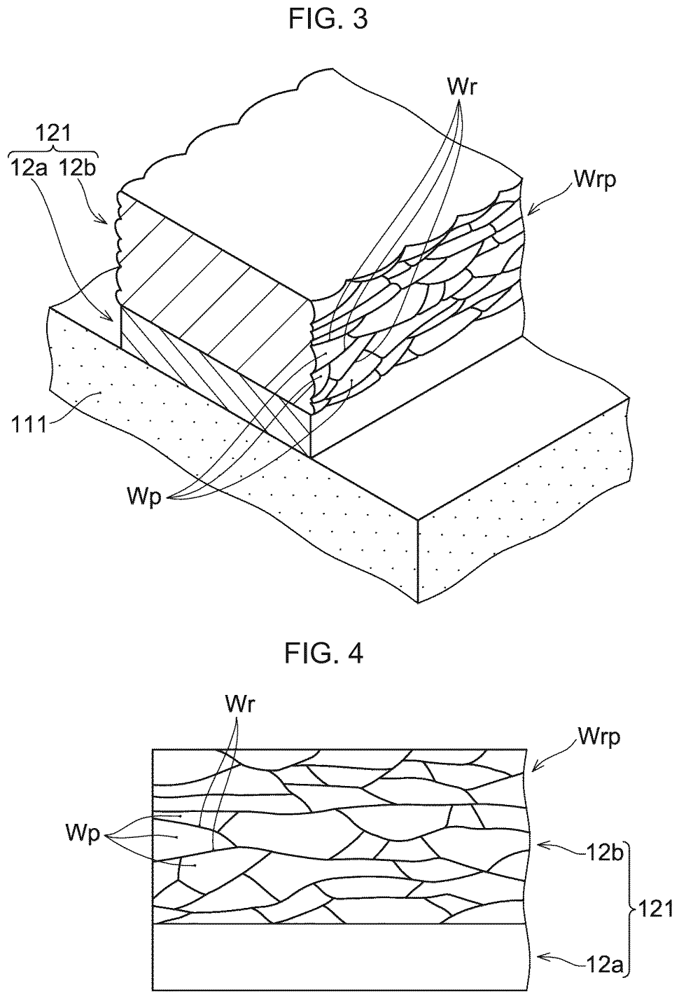

Next, with reference to FIGS. 3 and 4, the unevenness (Wrp) formed on the side surface of the first conductor layer 121 is described in detail. FIG. 3 is a perspective view of the first conductor layer 121 when the first conductor layer 121 is viewed along an arrow (III) in FIG. 2. FIG. 4 illustrates the side surface of the first conductor layer 121 when the first conductor layer 121 is viewed along an arrow (IV), which is perpendicular to the side surface of the first conductor layer 121, in FIG. 2. In FIGS. 3 and 4, the second insulating layer 112 that covers the first conductor layer 121 is omitted.

As illustrated in FIGS. 3 and 4, the unevenness (Wrp) formed on the side surface of the first conductor layer 121 has a mesh-like pattern. Specifically, the unevenness (Wrp) is formed as a mesh-like uneven structure including multiple protrusions (Wp) and recesses (Wr) that are boundaries between the protrusions (Wp). Here, “mesh-like” means a pattern composed of cells corresponding to openings of a mesh and boundaries between the cells corresponding to strands of the mesh. That is, the unevenness (Wrp) includes the multiple protrusions (Wp) corresponding to multiple cells of a mesh, and the recesses (Wr) corresponding to boundaries between the cells of the mesh.

As illustrated in FIG. 4, in the mesh-like unevenness (Wrp) formed on the side surface of the first conductor layer 121, the multiple protrusions (Wp) corresponding to the cells of the mesh have different planar shapes (shapes recognized in the field of view of FIG. 4) and planar areas (areas recognized in the field of view of FIG. 4). Further, extension directions of the groove-shaped recesses (Wr) along the boundaries between the cells of the mesh are not limited to a specific direction, and the recesses (Wr) extend in irregular directions according to the planar shapes of the protrusions (Wp). It is thought that, because the recesses (Wr) extend in multiple different directions, stronger adhesion between the first conductor layer 121 and the second insulating layer 112 (see FIG. 2) described above can be achieved.

Specifically, in the mesh-like unevenness (Wrp) formed on the side surface of the first conductor layer 121, the protrusions (Wp) corresponding to the cells of the mesh preferably have a maximum planner area of 0.1 μm² or less. The number of protrusions (Wp) per unit area on the side surface of the first conductor layer 121 can be secured at or above a desired number. Therefore, it is thought that stronger adhesion between the first conductor layer 121 and the second insulating layer 112 (see FIG. 2) can be achieved.

It is preferable that the mesh-like unevenness (Wrp) is formed such that a shortest distance in a direction perpendicular to the side surface of the first conductor layer 121 between a highest point (a point most protruded in the direction perpendicular to the side surface of the first conductor layer 121) among the multiple protrusions (Wp) constituting the unevenness (Wrp) and a deepest point (a point most recessed in the direction perpendicular to the side surface of the first conductor layer 121) of the recesses (Wr) is 0.3 μm or more and 1.0 μm or less. It is thought that, by setting the distance between the highest point of the protrusions (Wp) and the deepest point of the recesses (Wr) within this range, width dimensions of the conductor patterns of the first conductor layer 121 can faithfully follow designed dimensions while achieving good adhesion between the first conductor layer 121 and the second insulating layer 112 (see FIG. 2).

In the wiring substrate of the embodiment, among the conductor layers 12 that constitute the wiring substrate, it is sufficient that any of the conductor layers that include the wirings (FW) has mesh-like unevenness. Further, mesh-like unevenness may be formed on all side surfaces of the conductor layers included in the wiring substrate.

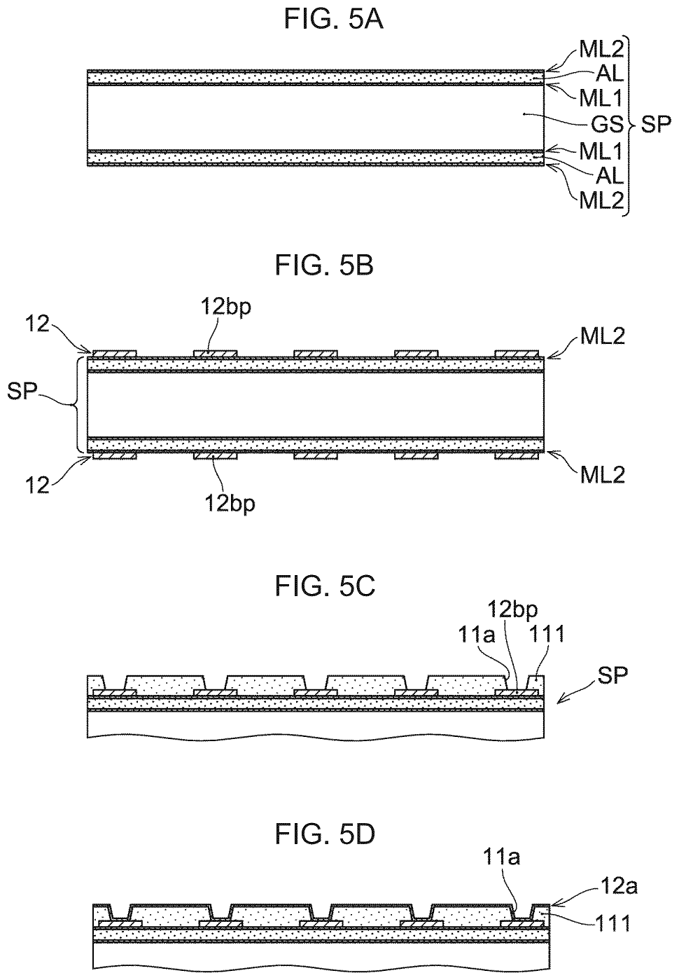

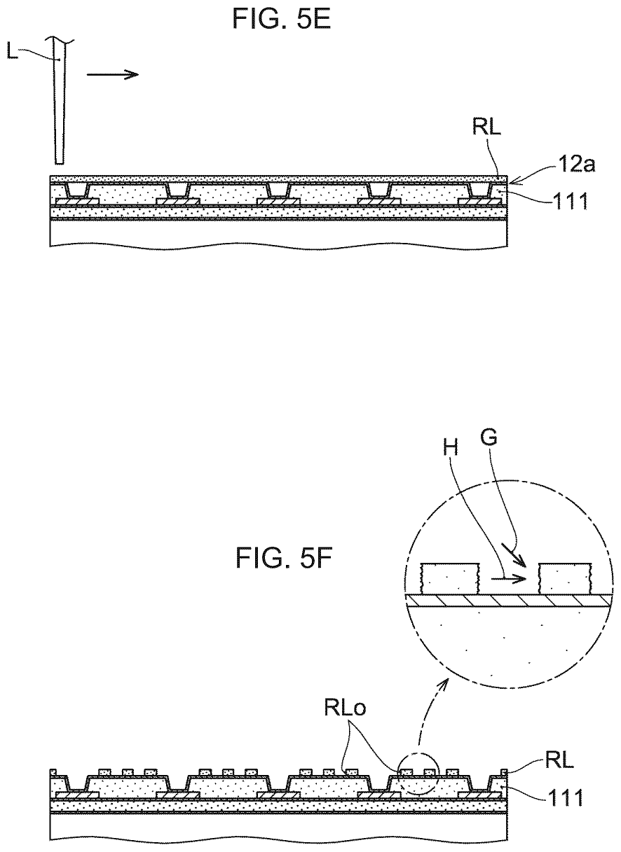

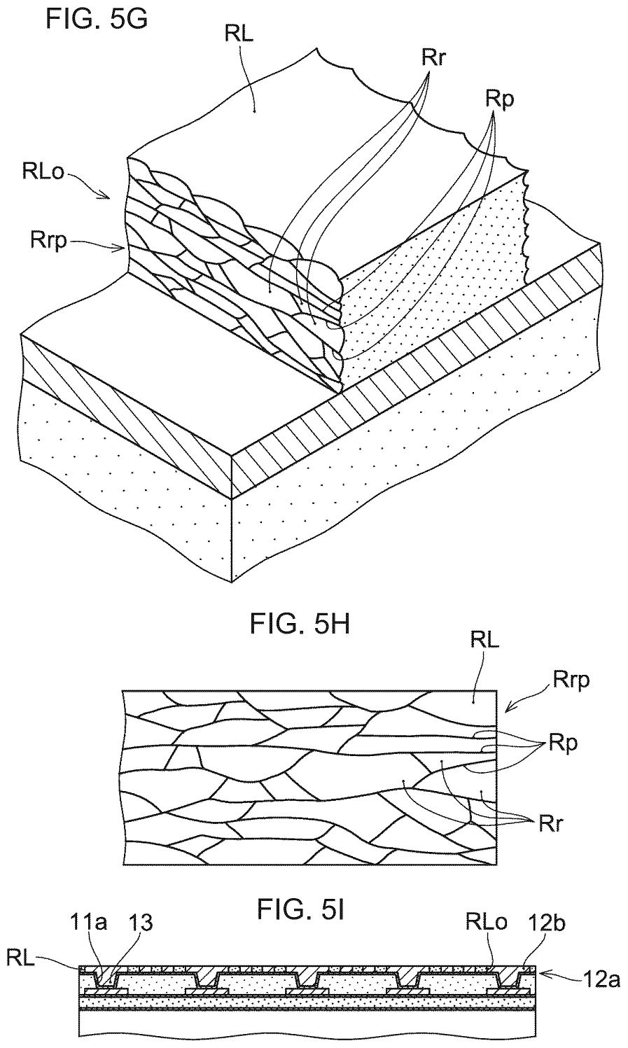

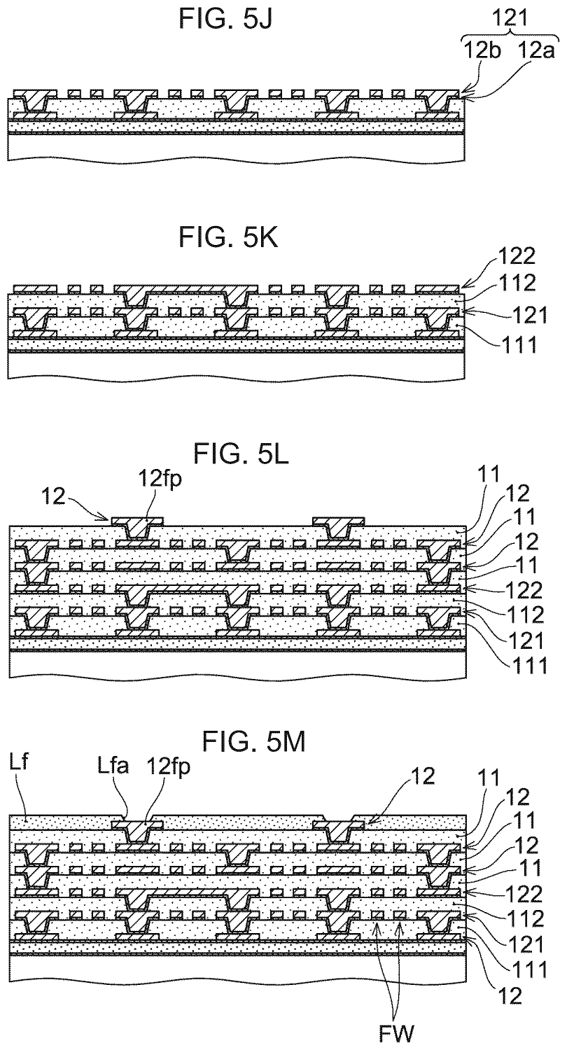

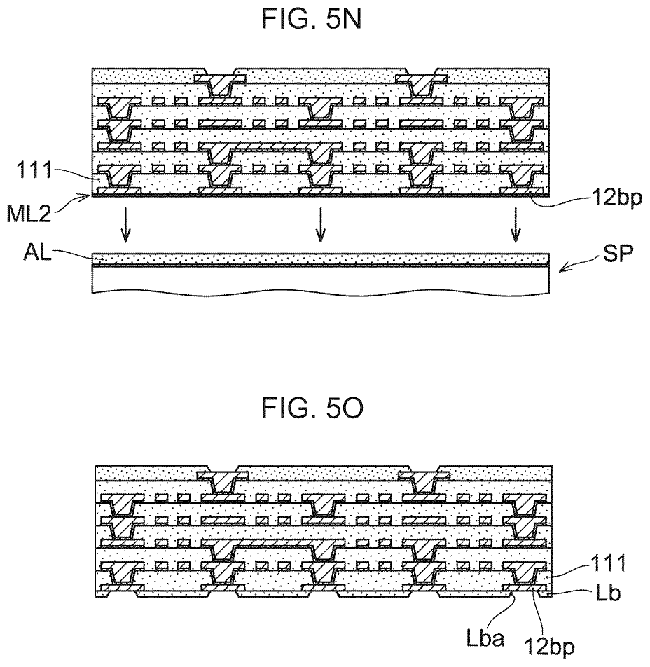

Next, with reference to FIGS. 5A to 5O, a method for manufacturing the wiring substrate of the embodiment is described, using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. In the following description about the method for manufacturing the wiring structure 1, a side closer to a core material (GS) constituting a support substrate (SP) is referred to as “lower” or a “lower side”, and a side farther from the support substrate (SP) is referred to as “upper” or an “upper side”. Therefore, of each of the elements constituting the wiring structure 1, a surface facing the support substrate (SP) is referred to as a “lower surface”, and a surface facing the opposite side with respect to the support substrate (SP) is also referred to as an “upper surface”. Further, in the description of the manufacturing method, similar to the description of the wiring substrate with reference to FIGS. 2 to 4, for the sake of simplicity, the insulating layer closest to the support substrate (SP) is referred to as the first insulating layer 111, the conductor layer formed in contact with the first insulating layer 111 is referred to as the first conductor layer 121, the insulating layer formed on the first conductor layer 121 is referred to as the second insulating layer 112, and the conductor layer formed in contact with the second insulating layer 112 is referred to as the second conductor layer 122.

First, as illustrated in FIG. 5A, the support substrate (SP) is prepared. In a method for manufacturing a wiring substrate according to an embodiment of the present invention, the support substrate (SP) to be used has good flatness on its two surfaces orthogonal to its thickness direction. The support substrate (SP) includes, for example, the core material (GS), which is a glass substrate, a first metal film layer (ML1) laminated on surfaces on both sides of the core material (GS), and a second metal film layer (ML2) laminated on the first metal film layer (ML1) via an adhesive layer (AL). The first and second metal film layers (ML1, ML2) are metal film layers formed by, for example, electroless plating or sputtering. The first and second metal film layers (ML1, ML2) are each depicted as a single layer in the illustration, but may each include multiple layers. For example, the first and second metal film layers (ML1, ML2) can each have a two-layer structure including a titanium layer and a copper layer. The adhesive layer (AL) can contain, for example, an azobenzene-based polymer adhesive that can be attached or detached by irradiation with light. The support substrate (SP) can include, as the core material (GS), a silicon substrate, a metal substrate, or a ceramic substrate instead of a glass substrate.

Next, as illustrated in FIG. 5B, a conductor layer 12 having multiple conductor pads (12bp) is formed on the support substrate (SP). In forming the conductor layer 12 in contact with the support substrate (SP), for example, a plating resist is formed on the second metal film layer (ML2), and openings corresponding to pattern formation regions of the conductor pads (12bp) are formed in the plating resist, for example, using a photolithography technology. Next, a plating film layer is formed in the openings by electrolytic plating using the second metal film layer (ML2) as a seed layer. After the formation of the plating film layer, the plating resist is removed, and a state illustrated in FIG. 5B is formed.

Next, as illustrated in FIG. 5C, the first insulating layer 111 is laminated to cover the upper and side surfaces of the conductor layer 12, as well as the surface of the support substrate (SP) exposed from the conductor patterns of the conductor layer 12. As the first insulating layer 111, for example, an insulating resin such as an epoxy resin or a phenol resin can be used. A fluorine resin, a liquid crystal polymer (LCP), a fluoroethylene resin (PTFE), a polyester resin (PE), or a modified polyimide resin (MPI) also may be used. The first insulating layer 111 is formed by thermocompression bonding these resins molded into a film-like shape. Next, the through holes (11a) are formed at formation positions of the via conductors 13 (see FIG. 1) in the first insulating layer 111, for example, by irradiation with CO₂ laser, excimer laser, or the like.

Although not illustrated, the formation of the through holes (11a) by irradiation with laser such as CO₂ laser can be performed by irradiating the laser while protecting the upper surface of the first insulating layer 111 by covering the upper surface with a protective film such as a polyethylene terephthalate (PET) film. The through holes (11a) penetrating the protective film and the first insulating layer 111 are formed. Further, after the formation of the through holes (11a), a desmear treatment may be performed to prevent a decrease in adhesion or an increase in a resistance component or the like of the via conductors 13 due to a processing-deformed substance occurring at bottoms of the through holes (11a). The desmear treatment can preferably be a dry desmear treatment using a plasma gas. The desmear treatment may also be performed while protecting the surface of the first insulating layer 111 in a state in which a protective film such as a polyethylene terephthalate (PET) film is formed on the surface of the first insulating layer 111.

In FIG. 5C, as well as in FIGS. 5D to 5F and 5I to 5O to be referenced below, the laminate formed on the surface on one side of the support substrate (SP) is illustrated, and illustration of the laminate that can be formed on the surface on the opposite side is omitted. However, on the surface on the opposite side of the support substrate (SP), a laminate with a similar structure and number of layers, or conductor layers and insulating layers with structures and number of layers different from those on the surface on the one side, may be formed, or it is also possible that such conductor layers and insulating layers are not formed.

Next, as illustrated in FIG. 5D, the metal film layer (12a) is formed on inner walls of the through holes (11a) and on the surface of the first insulating layer 111 by electroless plating, sputtering, or the like. Preferably, the metal film layer (12a) can be a sputtering film formed by sputtering. When a protective film is provided on the surface of the first insulating layer 111 during the formation of the through holes (11a) and/or during the desmear treatment, the protective film can be peeled off and removed before the formation of the metal film layer (12a). If a protective film is provided on the surface of the first insulating layer 111 during the formation of the through holes (11a) and/or during the desmear treatment, the protective film may be peeled off and removed before formation of the metal film layer (12a).

Next, as illustrated in FIG. 5E, for example, a dry film resist containing a photosensitive epoxy resin is adhered onto the metal film layer (12a), to form a resist layer (RL). Subsequently, the resist layer (RL) is subjected to exposure. In the method for manufacturing the wiring substrate of the embodiment, direct imaging exposure is performed in the process of exposing the resist layer (RL). In the direct imaging exposure, a photomask is not used, and irradiation light (L) is directly irradiated onto the resist layer (RL). As a light source for the irradiation light (L), for example, a semiconductor laser with a wavelength of 350 nm to 410 nm or an ultra-high-pressure mercury lamp can be used. The irradiation light (L) is scanned according to drawing patterns corresponding to the conductor patterns of the first conductor layer 121 to be formed on the first insulating layer 111 (see FIG. 1). In the exposure, an irradiation spot of the irradiation light (L) is scanned multiple times over a portion of the resist layer (RL) to be exposed. That is, a specific location of the resist layer (RL) to be exposed is subjected to multiple exposure by the irradiation light (L).

Next, as illustrated in FIG. 5F, resist patterns corresponding to the conductor patterns of the first conductor layer 121 to be formed on the first insulating layer 111 (see FIG. 1) are formed in the resist layer (RL). Specifically, after the above-described process of exposing the resist layer (RL) is completed, the resist layer (RL) is developed to form openings (RLo), using a developer including a sodium carbonate aqueous solution which can contain, for example, a surfactant, a defoaming agent, a small amount of an organic solvent for promoting development, and the like. The openings (RLo) corresponding to the wirings (FW) to be formed on the first insulating layer 111 are formed to have a minimum opening width of 3 μm or less and a minimum inter-opening distance of 3 μm or less.

In the exposure of the resist layer (RL) described above with reference to FIG. 5E, when the irradiation light (L) is irradiated onto the resist layer (RL), a standing wave is generated by the irradiation light (L) and reflected light of the irradiation light (L) reflected by the metal film layer (12a). Due to this standing wave, variation in concentration of the photosensitive material in the resist layer (RL) occur in a thickness direction of the resist layer (RL). In direct imaging exposure, the irradiation light (L) is scanned while being repeatedly and overlappingly irradiated onto a specific location to be exposed. It is thought that this multiple exposure by the irradiation light (L) results in irregular variations in the concentration of the photosensitive material contained in the resist layer (RL) in both the thickness direction and planar direction of the resist layer (RL). Therefore, as described above with reference to FIG. 5F, on sidewalls (inner wall surfaces) of the openings (RLo) formed as a result of the development of the resist layer (RL), an uneven shape due to the irregular variations in the concentration of the photosensitive material is formed.

FIG. 5G illustrates a perspective view of the resist layer (RL) when viewed along an arrow (G) in FIG. 5F. Further, FIG. 5H illustrates a side view of a sidewall of an opening (RLo) in the resist layer (RL) when viewed along an arrow (H), which is perpendicular to the sidewall of the opening (RLo), in FIG. 5F. As illustrated in FIG. 5G, unevenness (Rrp) is formed on the sidewalls of the openings (RLo) in the resist layer (RL). Specifically, the unevenness (Rrp) is formed as a mesh-like uneven structure including multiple recesses (Rr) and protrusions (Rp) that are boundaries between the multiple recesses (Rr). That is, the unevenness (Rrp) includes the multiple recesses (Rr) corresponding to cells of a mesh and the protrusions (Rp) corresponding to boundaries between the cells of the mesh.

As illustrated in FIG. 5H, in the mesh-like unevenness (Rrp) formed in the resist layer (RL), the multiple recesses (Rr) corresponding to the cells of the mesh have different planar shapes (shapes recognized in the field of view of FIG. 5H). Further, the multiple recesses (Rr) corresponding to the cells of the mesh have different planar area (areas recognized in the field of view of FIG. 5H). The mesh-like unevenness (Rrp) can be formed such that the recesses (Rr) have a maximum planar area of 0.1 μm² or less. Further, extension directions of the protrusions (Rp) corresponding to the boundaries between the cells of the mesh are not limited to a specific direction, and the protrusions (Rp) extend in irregular directions according to the planar shapes of the recesses (Rr). The maximum planar area of the recesses (Rr) in the unevenness (Rrp) can be adjusted by appropriately controlling exposure conditions, such as a spot diameter, a wavelength, and a scanning speed of the irradiation light (L), in the direct imaging exposure of the resist layer (RL) using the irradiation light (L), as described with reference to FIG. 5E.

Next, as illustrated in FIG. 5I, the plating film layer (12b) is formed in the openings (RLo) of the resist layer (RL) by electrolytic plating using the metal film layer (12a) as a power feeding layer. The via conductors 13 are formed by completely filling the through holes (11a) with the plating film layer (12b). The plating film layer (12b) formed in the openings (RLo) is molded into a shape that replicates the mesh-like unevenness (Rrp) (see FIG. 5G) formed on the sidewalls of the openings (RLo) at portions in contact with the sidewalls.

Next, the resist layer (RL) is removed using an alkaline peeling solution. By the removal of the resist layer (RL), the side surface of the plating film layer (12b) is exposed, which has a mesh-like uneven shape replicating the mesh-like unevenness (Rrp) (see FIG. 5G). After the resist layer (RL) is removed, a portion of the metal film layer (12a) that is not covered by the plating film layer (12b) is removed by etching. No mesh-like unevenness is formed on a side surface of the metal film layer (12a) exposed by the etching. As illustrated in FIG. 5J, the first conductor layer 121 having a two-layer structure formed of the metal film layer (12a) and the plating film layer (12b) is formed.

Next, as illustrated in FIG. 5K, the second insulating layer 112 is formed on the first conductor layer 121 and on the first insulating layer 111 exposed from the conductor patterns of the first conductor layer 121, and further, the second conductor layer 122 is formed on the second insulating layer 112, using methods similar to those used for forming the first insulating layer 111 and the first conductor layer 121. In the formation of the second insulating layer 112, an uncured second insulating layer 112 fills the recesses of the mesh-like uneven shape formed on the side surface of the first conductor layer 121, resulting in good adhesion between the second insulating layer 112 and the first conductor layer 121. The upper surface of the first conductor layer 121, where the mesh-like uneven shape is not formed, has good flatness, and therefore, the upper surface of the second insulating layer 112 is also formed as a surface with relatively good flatness. It is thought that the conductor patterns of the second conductor layer 122, which is formed in contact with the upper surface of the second insulating layer 112, can be formed with dimensions that faithfully follow design values.

Next, as illustrated in FIG. 5L, using methods similar to those used for forming the first insulating layer 111 and the first conductor layer 121, a desired number of insulating layers 11 and conductor layers 12 are laminated on the second conductor layer 122 and the second insulating layer 112. The uppermost conductor layer 12 is formed into a pattern that includes the conductor pads (12fp).

Next, as illustrated in FIG. 5M, the solder resist layer (Lf) is formed by forming a photosensitive epoxy resin or polyimide resin layer on the surfaces of the insulating layer 11 and the conductor layer 12, and the openings (Lfa) that define the conductor pads (12fp) are formed using a photolithography technology.

In the method for manufacturing the wiring substrate of the embodiment, it is sufficient that at least one of the conductor layers that include fine wirings is formed using a method that includes direct imaging exposure of a resist layer, resulting in the formation of openings with mesh-like uneven shapes on their sidewalls. All of the conductor layers constituting the wiring substrate may be formed using a method that includes the formation of openings with mesh-like unevenness through direct imaging exposure of a resist layer. Therefore, for example, in the illustrated example, the lowermost conductor layer 12 (the conductor layer 12 in contact with the support substrate (SP)), which does not include the wirings (FW), may also be formed using a method that includes the formation of openings with mesh-like unevenness through direct imaging exposure. Further, the uppermost conductor layer 12, which does not include the wirings (FW), may also be formed using a method that includes the formation of openings with mesh-like unevenness through direct imaging exposure of a resist layer.

Next, as illustrated in FIG. 5N, the support substrate (SP) is removed. The lower surface of the second metal film layer (ML2) below the conductor pads (12bp) is exposed. In the removal of the support substrate (SP), for example, the adhesive layer (AL) is irradiated with laser and is softened, after which the second metal film layer (ML2) of the support substrate (SP) is peeled off.

Next, the second metal film layer (ML2) is removed by etching, exposing the lower surfaces of the conductor pads (12bp) and the lower surface of the first insulating layer 111. On the lower surfaces of the conductor pads (12bp) and on the lower surface of the first insulating layer 111, the solder resist layer (Lb) is formed by forming a photosensitive epoxy resin or polyimide resin layer on the surfaces of the insulating layer 11 and conductor layer 12. In the solder resist layer (Lb), the openings (Lba) that define the conductor pads (12bp) are formed using a photolithography technology. The manufacture of the wiring substrate 1 is completed.

The wiring substrate of the embodiment is not limited to those having the structures illustrated in the drawings or those having the structures or materials exemplified in the present specification. For example, the wiring substrate of the embodiment can have any number of insulating layers and conductor layers. The uppermost and lowermost conductor layers of the wiring substrate can include conductor patterns in addition to the conductor pads.

The method for manufacturing the wiring substrate of the embodiment is not limited to the method described with reference to FIGS. 5A-5O, and the conditions, processing order or the like of the method can be modified as desired. It is sufficient that the method for manufacturing the wiring substrate of the embodiment includes at least forming openings having mesh-like unevenness on their sidewalls in a resist layer on a metal film layer by direct imaging exposure, and forming a plating film layer with unevenness replicating the mesh-like unevenness in the openings. Depending on a structure of an actually manufactured wiring substrate, some of the processes may be omitted, or other processes may be added.

Japanese Patent Application Laid-Open Publication No. 2000-252622 describes a printed wiring substrate in which a conductor circuit is formed on a resin insulating layer. A surface of the conductor circuit is roughened with a chemical solution, and a resin insulating layer is further formed on the conductor circuit.

In Japanese Patent Application Laid-Open Publication No. 2000-252622, the surface (including side and upper surfaces) of the conductor circuit is roughened by etching with a chemical solution. It is thought that it may be difficult to achieve a desired wiring thickness for wirings included in the conductor circuit.

A wiring substrate according to an embodiment of the present invention includes: a first insulating layer; a first conductor layer formed on the first insulating layer; and a second insulating layer formed on the first insulating layer and on the first conductor layer. The first conductor layer includes wirings having a minimum wiring width of 3 μm or less and a minimum inter-wiring distance of 3 μm or less. Mesh-like unevenness is formed on a side surface of the first conductor layer, and the mesh-like unevenness is not formed on an upper surface of the first conductor layer.

A method for manufacturing a wiring substrate according to an embodiment of the present invention includes: forming a metal film layer on a first insulating layer; forming a resist layer having openings on the metal film layer; and forming a plating film layer on the metal film layer in the openings. The forming of the resist layer includes exposing the resist layer by direct imaging exposure to form the openings having mesh-like unevenness on side walls thereof. The forming of the plating film layer includes forming an uneven shape on a side surface of the plating film layer that replicates the mesh-like unevenness.

According to an embodiment of the present invention, it is thought that a wiring substrate is provided in which good adhesion between the first conductor layer and the second insulating layer is achieved by forming the mesh-like unevenness on the side surface of the first conductor layer and the wirings are formed to a desired thickness by not forming the mesh-like unevenness on the upper surface of the first conductor layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first insulating layer;
a conductor layer formed on the first insulating layer; and
a second insulating layer formed on the first insulating layer such that the second insulating layer is covering the conductor layer,
wherein the conductor layer includes a plurality of wirings formed such that the wirings have a minimum wiring width of 3 μm or less and a minimum inter-wiring distance of 3 μm or less and that the conductor layer has mesh-like unevenness formed on a side surface of the conductor layer and not on an upper surface of the conductor layer.

2. The wiring substrate according to claim 1, wherein the conductor layer includes a metal film layer formed in contact with the first insulating layer and a plating film layer formed on the metal film layer such that the mesh-like unevenness is formed on the plating film layer and not on the metal film layer.

3. The wiring substrate according to claim 1, wherein the conductor layer is formed such that the mesh-like unevenness has protrusions corresponding to cells of a mesh and recesses corresponding to boundaries between the cells.

4. The wiring substrate according to claim 3, wherein the mesh-like unevenness of the conductor layer is formed such that the cells of the mesh-like unevenness have a maximum planar area of 0.1 μm² or less.

5. The wiring substrate according to claim 3, wherein the mesh-like unevenness of the conductor layer is formed such that a shortest distance between a deepest point of the recesses and a highest point of the protrusions in a direction perpendicular to the side surface of the conductor layer is in a range of 0.3 μm to 1.0 μm.

6. The wiring substrate according to claim 1, further comprising:
a second conductor layer formed on the second insulating layer.

7. The wiring substrate according to claim 2, wherein the conductor layer is formed such that the mesh-like unevenness has protrusions corresponding to cells of a mesh and recesses corresponding to boundaries between the cells.

8. The wiring substrate according to claim 7, wherein the mesh-like unevenness of the conductor layer is formed such that the cells of the mesh-like unevenness have a maximum planar area of 0.1 μm² or less.

9. The wiring substrate according to claim 7, wherein the mesh-like unevenness of the conductor layer is formed such that a shortest distance between a deepest point of the recesses and a highest point of the protrusions in a direction perpendicular to the side surface of the conductor layer is in a range of 0.3 μm to 1.0 μm.

10. The wiring substrate according to claim 2, further comprising:
a second conductor layer formed on the second insulating layer.

11. The wiring substrate according to claim 3, further comprising:
a second conductor layer formed on the second insulating layer.

12. The wiring substrate according to claim 4, wherein the mesh-like unevenness of the conductor layer is formed such that a shortest distance between a deepest point of the recesses and a highest point of the protrusions in a direction perpendicular to the side surface of the conductor layer is in a range of 0.3 μm to 1.0 μm.

13. The wiring substrate according to claim 4, further comprising:
a second conductor layer formed on the second insulating layer.

14. The wiring substrate according to claim 5, further comprising:
a second conductor layer formed on the second insulating layer.

15. The wiring substrate according to claim 8, wherein the mesh-like unevenness of the conductor layer is formed such that a shortest distance between a deepest point of the recesses and a highest point of the protrusions in a direction perpendicular to the side surface of the conductor layer is in a range of 0.3 μm to 1.0 μm.

16. The wiring substrate according to claim 8, further comprising:
a second conductor layer formed on the second insulating layer.

17. The wiring substrate according to claim 15, further comprising:
a second conductor layer formed on the second insulating layer.

18. A method for manufacturing a wiring substrate, comprising:
forming a metal film layer on a first insulating layer;
forming a resist layer having openings on the metal film layer; and
forming a plating film layer on the metal film layer in the openings formed in the resist layer,
wherein the forming of the resist layer includes exposing the resist layer by direct imaging exposure such that the openings have mesh-like unevenness formed on side walls of the resist layer in the openings, and the forming of the plating film layer includes forming an uneven shape on a side surface of the plating film layer such that the side surface of the plating film layer replicates the mesh-like unevenness.

19. The method for manufacturing a wiring substrate according to claim 18, wherein the forming of the resist layer includes exposing the resist layer by the direct imaging exposure such that the mesh-like unevenness has protrusions corresponding to cells of a mesh and recesses corresponding to boundaries between the cells and that the cells of the mesh have a maximum planar area of 0.1 μm² or less.

20. The method for manufacturing a wiring substrate according to claim 18, wherein the forming of the openings includes forming openings having a minimum opening width of 3 μm or less and a minimum inter-opening distance of 3 μm or less.
